(19) United States
(12) Patent Application Publication
(10) Pub. No.: US 2021/0285899 A1
(43) Pub. Date: Sep. 16, 2021

(54) SPECIMEN CONTROL MEANS FOR PARTICLE BEAM MICROSCOPY

(71) Applicant: Gerasimos Daniel DANILATOS, New South Wales (AU)

(72) Inventor: Gerasimos Daniel DANILATOS, New South Wales (AU)

(21) Appl. No.: 16/622,736

(22) PCT Filed: Jun. 19, 2018
(86) PCT No.: PCT/AU2018/050605

§ 371 Date: Dec. 13, 2019

(30) Foreign Application Priority Data
Jun. 26, 2017 (AU) 2017902460
Jan. 22, 2018 (AU) 2018900200

(51) Int. Cl. G01N 23/20025; H01J 37/20

(52) U.S. Cl. CPC G01N 23/20025; H01J 37/20; G01N 2223/33; H01J 2237/2608; H01J 2237/2003; H01J 2237/202; H01J 2237/162

(57) ABSTRACT

Specimen control means are disclosed for use with multipurpose particle beam instruments, such as with SEM, ESEM, TESEM, TEM, ETEM and ion microscopes. It provides a control stage located outside a chamber with a flexible wall that allows specimen movement inside the chamber. The same stage can open or close the bottom of the chamber base carrying a specimen stub, which is transferred to and from a conveyor belt or carousel supplied with a multitude of stubs filled with new specimens for examination. The chamber is further supplied with directed gas controls to regulate its gaseous environment. There is a supply of clean gas to maintain the instrument and specimen free of contamination, or to provide a reactant gas for microfabrication, or to enhance signal detection in a microscope. Stationary charged particle beam instruments are equipped with micro-mechanical specimen scanning for use in ultra-high resolution particle beam technologies.

### TECHNICAL FIELD

The present invention relates to the technical field of charged particle beam technologies, such as electron and ion microscopy as well as to electron and ion beam technologies in general and to environmental electron microscopy in particular.

### BACKGROUND ART

Electron microscopes (EM) in general, employ either a scanned electron beam such as scanning electron microscopes (SEM), environmental scanning electron microscopes (ESEM), transmission environmental scanning electron microscopes (TESEM), scanning transmission electron microscopes (STEM), or a stationary electron beam such as conventional transmission electron microscopes (TEM) and environmental TEM (ETEM). Related technologies employ ion beams in lieu of or in addition to electron beams, with both classes of instruments delivering focused charged particle beams in a stationary or scanned mode. The employed beams are directed on the surface of a bulk specimen or through a thin section of a specimen. The specimens are handled by controlling the specimen environment or vacuum and the position by appropriate means.

All such instruments invariably employ enclosed specimen chambers (SC), inside which samples are positioned for examination under a beam. The need to provide a specimen chamber arises from the nature of particle beam used, which suffers severe scattering in the presence of an environmental gas around the specimen. This has generally necessitated the evacuation of gas to allow free beam travel over a long distance between the specimen and the instrument column. Alternatively, the beam travel distance and gas pressure are controlled inside a chamber to allow minimum beam scattering. As a result, historically, all said instruments are fitted with an enclosed chamber wall.

In consequence of the enclosed chamber, the employed means necessary (specimen stage) for the positioning and movement of specimens in x-y-z direction, also for rotation and tilt are invariably enclosed inside the said chamber, which is made with heavy duty walls to withstand the large forces generated by ambient pressure. The specimen transfer from ambient conditions to the vacuum or controlled environment in the chamber takes place via a port or airlock in conjunction with venting and evacuating the chamber by standard procedures. Various detectors and other specimen controls and general handling of the specimen are all confined and constrained by the said chamber walls, which restrict the scope of specimen examination in prior art, but which scope can be expanded in ways that are disclosed by the present invention.

### DISCLOSURE OF INVENTION

The general object of the present invention is to provide particular novel specimen control means that enhance the performance of charged particle beam instruments. The control means pertain to specimen positioning and movement and to gaseous environment, all of which enhance or free the use of instruments in ways not accessible by prior art.

In one aspect, the invention provides a specimen chamber with flexible walls or sealingly moving wall parts that permit the placement of a stage outside the chamber for the control of mechanical movement and positioning of the specimen placed inside the chamber; and with a sealingly locking but movable and removable port connecting the specimen with the external stage.

In another aspect, the invention provides means for directed (streamed) gas delivery at the specimen in order to prevent contamination of the instrument and specimen while permitting a desired gaseous environmental control.

In yet a further aspect, the invention provides mechanical scanning of specimen for instruments with a stationary particle beam.

The invention further provides any desired combination of the above said aspects.

The said flexible wall means comprise bellows, or a flexible spiral or mesh encased by flexible material in conjunction with swivelling or universal joints to transmit all possible specimen movements.

The said sealingly moving wall parts comprise sliding O-rings or gaskets together with swivelling or universal joints to transmit all possible specimen movements.

The said directed gas delivery comprises a gaseous stream along the said particle beam inside the specimen chamber.

The said mechanical scanning of specimen comprises continuous micromovement in the x-y direction so that the stationary beam sweeps a specimen area under examination in a raster form.

Advantages of the present invention are shorter specimen exchange times, more versatile supply of specimens, better specimen environmental controls, compactness in size and weight, better focussing of the beam with maximum image resolution, maximal environmental pressure limits and ease for computerization and automation of the overall instrument operation.

The inventive step of the present invention that was not obvious or anticipated by prior art in charged particle beam technologies consists in the use of a specimen control stage placed outside a specimen chamber, which is further assisted by means to direct gas and control the pressure and type of gas inside the chamber, which is further assisted by mechanical scanning of the specimen itself relative to a stationary beam.

### BRIEF DESCRIPTION OF DRAWINGS

FIG. 1 Diagram of the specimen chamber with bellows, specimen stage controls, specimen supply and delivery system, chamber pressure controls, chamber gas controls and supply.

FIG. 2 Diagram of a miniature specimen chamber with bellows, specimen/stub stage controls, chamber pressure gauge and leak valve.

FIG. 3 Diagram of a variant chamber port plate with annular bellows and rotational spindle holding the specimen/stub.

FIG. 4 Diagram of a variant chamber port plate holding sealable/movable piece with sealable universal joint carrying the specimen/stub.

FIG. 5 Diagram of a chamber bellows with custom made variable convolution pitch, convolution height and overall shape to allow maximum flexibility and strength for all shift movements and tilt, together with rotatable spindle holding the specimen stub.

FIG. 6 Diagram of a variant localised mini-chamber without bellows comprising only the specimen stub at close proximity to the PLA surrounded by an annular clean gas jet supply and an optional protective wall with opening at the bottom; the specimen movement is free via the accompanying motion stage.

FIG. 7 Diagram of localised mini-chamber with specimen stub that seals against the bottom of instrument allowing only x-y motion, while the chamber is efficiently pumped via the provided PLA.

FIG. 8 Diagram of localised mini-chamber with specimen stub that seals against the bottom of instrument allowing all three x-y-z motions, while the chamber is efficiently pumped via the provided PLA.

FIG. 9 Diagram with split specimen stub to allow micro-movement that is superimposed on the macro-movement provided by an external stage control for instruments with a stationary particle beam.

FIG. 10 Diagram with split specimen stub as in previous FIG. 9 with a thin specimen attached for examination by transmitted beam.

FIG. 11 Diagram as in previous FIG. 10 in upside-down orientation of column and fitted with various detectors including a light microscope.

FIG. 12 Diagram of specimen chamber in a transmission electron microscope with two small aperture diaphragms and specimen/transfer rod under ambient conditions.

FIG. 13 Diagram of an atmospheric or environmental specimen micro-chamber with small apertures and mechanical micro-scanning means inserted in a transmission electron microscope.

### BEST MODES FOR CARRYING OUT THE INVENTION

To assist with the understanding of the invention, reference will now be made to the accompanying drawings, which embody some examples of the invention, without limiting the scope of the invention.

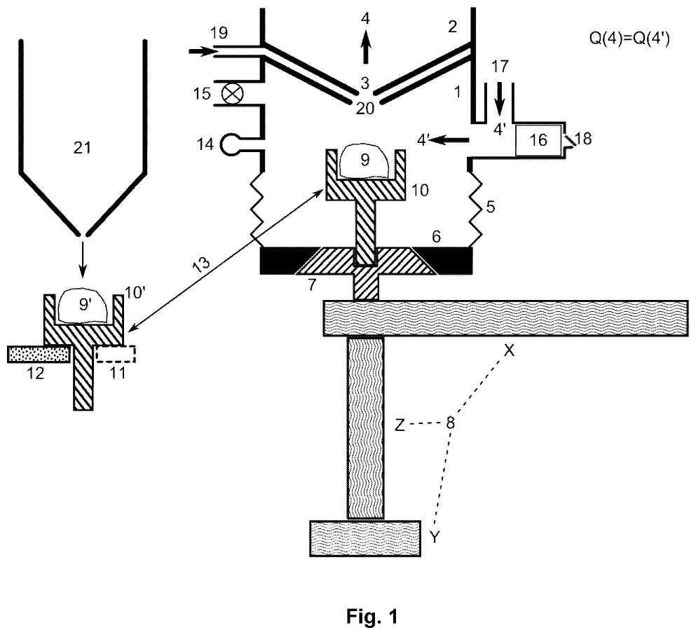

One embodiment of the present invention is shown in FIG. 1. A specimen chamber wall 1 fits at the end of an electron optics column 2, which is terminated by a pressure limiting aperture (PLA) 3 restricting the flow of gas 4 in the evacuated electron optics column. The chamber wall 1 is extended with a flexible wall consisting of a bellows or other flexible material 5, such as a spiral spring enveloped and supported in tandem with a space-suit-like material. The flexible wall is terminated with flange 6 bearing an opening that can be closed or opened with a suitably sealing plate 7 that is fixed on one arm of a motion control stage 8 providing at least three-dimensional movement in the x-y-z directions. A specimen for examination 9 is placed in the cavity of specimen holder (stub) 10 with a stem inserted securely in a blind hole of the sealing plate 7. In this configuration, the specimen is moved in the x-y-z direction via the stage 8 by the allowance provided by the flexible wall of the chamber. At the end of an examination, the specimen stub is moved first by lowering the plate 7 and then by shifting the arm in the x-direction until the stub is inserted in the empty slot 11 of a conveyor belt or carousel 12 bearing a multitude of stubs filled with new specimens 9′. By such means, a new specimen stub 10′ is transferred 13 in the specimen chamber by a reverse order of movements. It is critical that the plate 7 seals and locks against the flange 6 with suitable means to overcome the forces arising from the pressure difference between ambient and chamber pressures. Sealing means comprise an O-ring, or pad, or polished surfaces, etc. Locking means comprise the spring force from the bellows in compressed position, or the compression force from a spring, or locking clamps, or sliding slots, or swivelling locking grooves, or magnetic force, or any other practical locking device for the same purpose. The scope of the present invention is not limited by providing only x-y-z movement, but it can also include tilt and rotation of the specimen initially to the extent allowed by the flexibility of the bellows or other flexible material used. Rotation, in particular, can be allowed by the circular plate 7, depending on the locking means used, but it can also be allowed by other means as is subsequently described. The solid wall of the chamber is fitted with a pressure gauge 14, a gas leak valve 15 to regulate the admission of ambient gas in the chamber and a pump 16 to remove gas from the chamber, all of which in coordination assist in the regulation of any desired pressure level in the chamber, including vacuum (i.e. very low pressure). The pump 16 is preferably turned off once a desired pressure level is achieved, to avoid unnecessary strong streaming of gas other than the weak streaming created by the small leak through aperture 3. This describes the main embodiment of the invention, which is expanded by various other embodiments as described further below.

In another embodiment of the invention, the gas 4 leaking through the pressure limiting aperture 3, is returned into the chamber via ducting 17. When a steady state of the recirculating gas is achieved, we obtain the condition that the amount of leaking gas Q(4) is equal to the amount of returning gas Q(4′), i.e. Q(4)=Q(4′), whereupon the leak valve 15 is closed, the pump 16 is turned off or isolated from the chamber and/or a flap or other valve 18 is shut sealed.

In yet a further embodiment, a clean or control gas is supplied to the chamber via an inlet 19 close to the PLA in order to provide a contamination free gaseous region immediately below the PLA by directing gas along the beam towards the specimen. In one option, the clean gas is delivered with a needle but in another preferred option the gas is delivered with an annular opening 20 surrounding the PLA 3. The gas jet formed in the vicinity of the PLA is generally at the lowest subsonic speed that is sufficient to create a clean zone without disturbing the specimen. However, when required, the subsonic speed is increased by increasing the gas supply pressure, so that the jet is used to remove loose particles from the surface of the specimen to expose the underlying material layer or to prevent dust particles entering the column via the PLA.

In yet another embodiment, the above said gas supply serves the purpose of providing a controlled reaction with the specimen surface as used in microfabrication.

In yet another embodiment, the nature of the said gas is chosen to enhance the gaseous detection device (GDD) usually employed in an ESEM.

In yet another embodiment, the said gas supply is delivered at supersonic speed inducing a pumping action of gas flowing from the electron optics column towards the chamber, as disclosed by prior art patent D1, also known as reverse flow PLA.

It is important that in all above embodiments provided with a clean or control gas supply, there must be also removal of the supplied gas via suitable means, like via the pump 16 if a hypobaric pressure level is required (i.e. below ambient pressure) or via a loose fit of plate 7 breaking the seal and letting the excess gas out of the chamber at ambient level but with a clean gas or a gas of choice for specific purposes. With a sealed chamber, it is again preferable to balance the supply of gas with the leaking gas through aperture 3, whilst pump 16 operates only during pressure level adjustment.

Depending on the industrial application, the leak valve 15 and clean gas supply at inlet 19 can be combined or substitute each other in one single inlet.

Optionally, the specimens are supplied to the said conveyor belt or carousel by a sample filling station 21 manually or automatically operated. The entire operation of described specimen exchange and chamber environment control can be computerized and automated to increase productivity and efficiency.

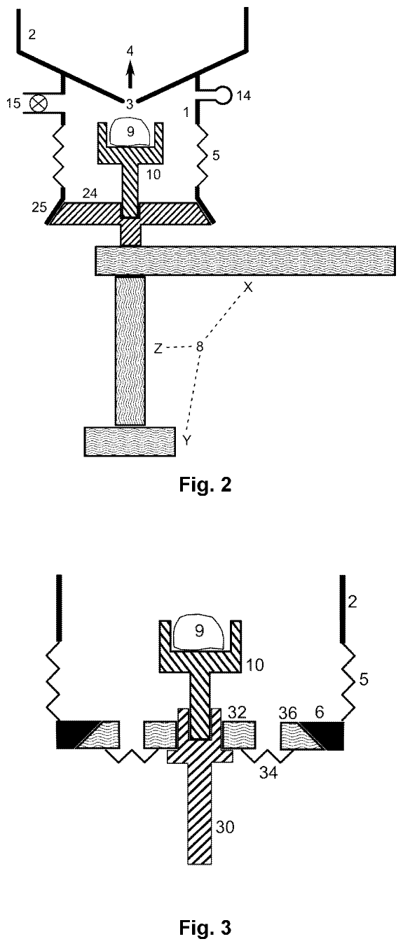

In a variant embodiment shown in FIG. 2, a mini-chamber is achieved by eliminating most of the above mentioned controls, whilst retaining only a pressure gauge 14, a leak valve 15 and a chamber base plate 24 that plugs sealingly at the bottom flange (rim) 25 of a side wall bellows. This is coupled again with an external control stage supplying the desired specimen movement inside the chamber. Due to the very small volume of chamber now possible, the leaking gas through PLA 3 provides sufficient pumping action to lower the pressure to a desired level on condition that the PLA is large enough to allow fast enough pumping speed. This practical embodiment is made possible only with the present invention by virtue of placing the control stage outside the chamber, which leaves only the specimen and specimen stub size to limit the smallest mini-chamber volume.

In a further embodiment shown in FIG. 3, the previously used port plate 7 per FIG. 1 is now compounded and comprises an annular bellows 34 held between two annular pieces 32 and 36 together with a rotating but sealable spindle 30 holding the specimen stub 10. The described composite port plate is movable and removable by an external stage as previously described to achieve specimen positioning and replacement. By this embodiment, an increased amount of tilt and rotation can be obtained.

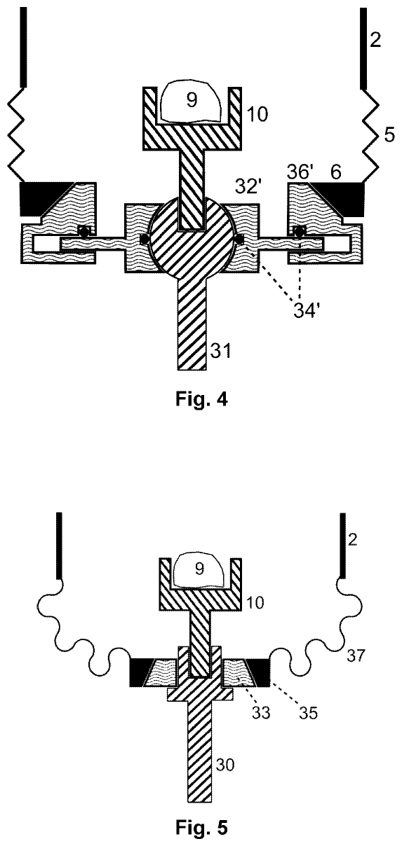

In yet another embodiment shown in FIG. 4, the previously rotating spindle 30 per FIG. 3 is replaced with a universal joint 31 within a movable piece 32′ held by piece 36′. Suitable sealing means 34′ are used between all moving surfaces. This embodiment provides enhanced simultaneous rotation and tilt of the specimen.

In yet a further embodiment shown in FIG. 5, a custom designed and made bellows 37 provides maximum flexibility to allow three directional movement and tilt, whilst an axial spindle 30 inside a movable port plate 33 allows full rotation of the specimen stub 10. The plate 33 seals and locks against flange 35. The said bellows 37 is achieved by a variable convolution pitch, convolution height and bellows gross shape. The gross shape can be a truncated cone in the upright or inverted position in accordance with the requirements of application and associated stage control means.

In all above embodiments, the movable port plate is locked sealably at the bottom of the chamber by suitable means. Sealing means may comprise O-rings, gaskets, appropriate suitable flange fittings, etc. Locking means may comprise magnetic force, spring force, flaps, clamps, pins, grooves, etc. It should be appreciated that the choice of any or all of these practical engineering details does not depart from the spirit of the invention.

It should also be appreciated that the type, size, geometry, and materials chosen in the design and construction of any flexible wall used is determined by the actual ambient conditions of pressure and atmosphere, in which any given instrument is designed to operate. Said conditions vary in terrestrial and planetary environments, such as on Mars, where the pressure is two orders of magnitude lower than on Earth, but with an abundance of dust particles. It should be appreciated that the previous embodiments are provided by way of example only and do not exhaust other combinations of material means that achieve the spirit of the invention, namely, any chamber wall that allows the transmission of specimen movement by means external to the chamber. Some of these combinations can be illustrated by the following numerical examples:

With a cylindrical shape bellows, the lateral forces due to pressure cancel out and can be supported by the mechanical strength of the bellows wall. That leaves only the force exerted on the circular base. For a base diameter of 2 cm, the atmospheric pressure (100 kPa) on Earth exerts a force of 3.2 kg, if the chamber pressure is vacuum. This maximum force can be sustained by a hexapod (six-arm) stage, so that each arm would bear only 0.53 kg at the most, because this is greatly reduced and minimized by the bellows spring force in the compressed position. The hexapod can be mounted in inverted orientation to be supported by the column of the instrument, for stability and compactness. Furthermore, life is supported at ambient pressure greater than about 20 kPa, which is ⅕ of a full atmosphere, so that the maximum force would become only 0.1 kg per arm of the hexapod. If we then reduce the chamber base diameter by ½, then the force is further reduced by ¼, which is very small with no practical problems during implementation. In this and other examples, the bellows can be replaced with a fabric material supported by or embedded with a mesh structure that allows both strength and flexibility with a variable deformation to allow all motions provided by a hexapod or by any other mechanical stage or combinations thereof. The bellows or other flexible wall principle can be highly suitable for Martian operations of a mini-ESEM instrument, since the pressure force ( 1/100 of that on Earth) becomes negligible allowing also the use of much larger size specimen chambers.

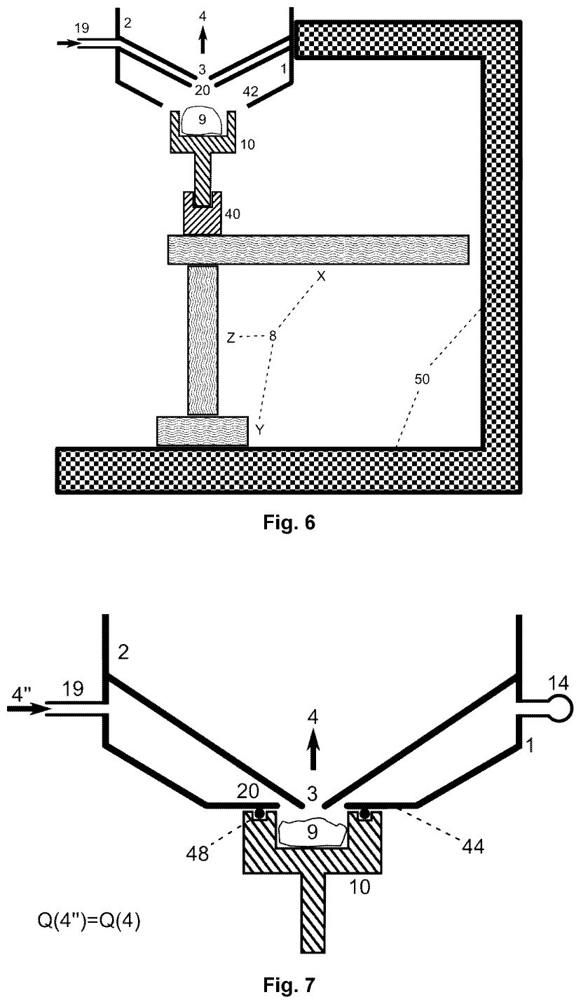

In a another drastic simplification of the chamber, FIG. 6 shows the elimination of all chamber walls and bellows, except optionally the retention of an open bottom wall 42 for the purpose of enclosing and protecting sensitive parts located at the bottom of the column. The previously said specimen stub is brought in the vicinity of the said PLA 3 and of the said outlet 20 of a clean/control gas supply 19 around the PLA. By this special configuration, the pressure at the specimen is the same as the ambient pressure but effectively creating an otherwise controlled local region above the specimen, while the specimen is free to move in any direction, tilt and rotation by the attached stage.

In all of the embodiments disclosed above and more to follow below, the said control stage is mechanically secured on a firm base connected solidly with the main instrument column, as for example is shown in FIG. 6 by 50. This is a practical engineering requirement to suppress vibration and specimen shifting relative to the point of specimen examination. The said stage can be mounted in any orientation including direct coupling with the instrument column for all practical purposes, as with a hexapod. This and other practical engineering considerations already known in prior art can be incorporated without departing from the spirit of the invention.

A special embodiment is further disclosed by FIG. 7, wherein the specimen stub 10 itself seals against a flat bottom 44 of the instrument with appropriate sealing means 48. Due to the very small volume of this configuration, the gas can be efficiently pumped out via the PLA 3 without the need of an ancillary pump. A controlled gas leak 4″ only is provided through the inlet 19 to compensate for the gas loss 4 via the said aperture, so that the gas flow rates Q(4)=Q(4″), when the desired pressure level monitored by gauge 14 is achieved. By this practical but simplified control means, only x-y-movement is allowed during specimen examination, whilst the z-motion is applied only during specimen exchange.

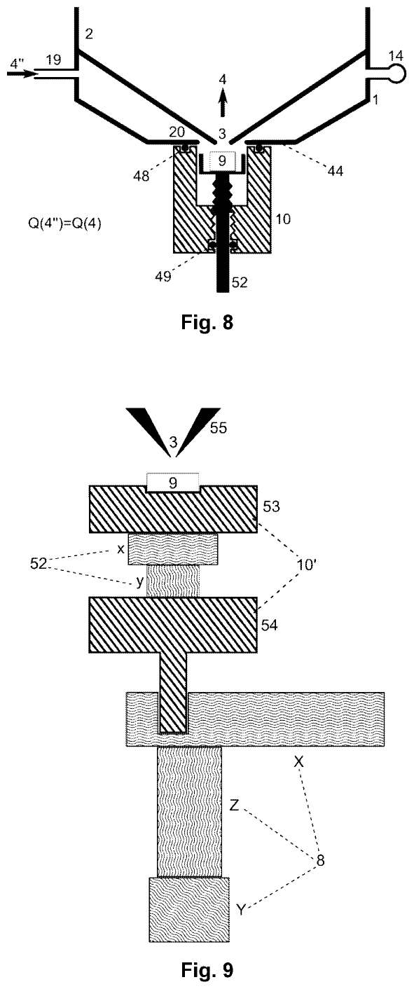

The previous embodiment is enhanced as shown in FIG. 8 by introducing z-shift during specimen examination with a moveable bottom of the stub via a threaded spindle 52 with sealable means 49. The threaded spindle can be replaced with other moving means such as with a piston driven by hydraulic pressure controls, or with a wire transmission through a tube without departing from the spirit of the invention.

Now, a breakthrough embodiment of the present invention is shown in FIG. 9, wherein the specimen itself is supplied with mechanical micro-scanning control means that move it relative to a stationary instrument beam. The said micro-control means is obtained by splitting the specimen stub 10′ to a moveable top part 53 relative to a bottom fixed part 54 secured onto the previously described stage 8. The two parts 53 and 54 are coupled with a micro-movement control stage 52 providing x-y movement and scanning means. The said micro-stage 52 is achieved with the use of piezo-electric elements providing deformation usually in the micron and submicron scale by an applied electrical signal. This type and related systems are known prior art in the technology of atomic force microscopy (AFM) and related technologies, whereby a mechanical probe (needle) is scanned over the surface of a specimen. The present invention calls for the use of same or adapted systems to transmit movement on the specimen itself that is consistent with the overall mechanical requirements of a micro-stage, as, for example, the specimen to be of particularly small size or mass. The great advantage of this embodiment is that it allows the use of a stationary beam, which disposes of (makes redundant) beam scanning means and greatly simplifies the design and construction of scanned beam instruments. Another great advantage of practical importance is that the PLA 3 at the end of a conical or sharp tip 55 can have an extremely small size required only to allow a given stationary beam through. For example, a focussed electron beam diameter is in the nm-scale, the expected best electron convergence angle is between 5-10 mrad, so that the PLA diameter can be in the micron-scale to allow focussing at sufficiently close distance from the aperture. Such a small PLA leaks only an extremely small amount of environmental gas through it into the vacuum of the electron optics column. In existing commercial instruments, the PLA has typically a diameter of 500 μm, so that a 1 μm diameter now would leak less than 250000× (times) gas, which can be handled by the existing vacuum systems even at one full atmosphere. The latter quantitative example creates a qualitative breakthrough (inventive step) in ESEM and TESEM technologies. Thus, by the embodiment of FIG. 9, the related instruments can get rid of both beam scanning means and extra pumping means to greatly simplify their design, construction and operation, while they allow practical use at any environmental pressure from vacuum to a full ambient atmosphere. However, these advantages are traded off by the disadvantage that the mechanical scanning of the specimen cannot be as fast as the fastest rate provided by scanning means of an electron beam, but they still allow a large number of applications not previously accessible by any other technology. The advantages of the use of small PLAs have been disclosed by prior art D1 and D2, which are now expanded by further reduction of the PLA size together with a stationary beam.

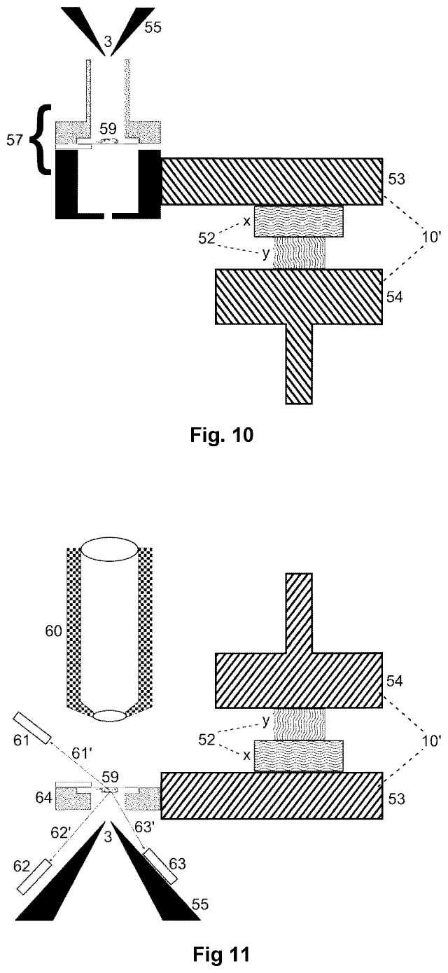

The previous embodiment is not limited to the examination of the surface of bulk specimens only, but it can be used also in TESEM mode and other transmission beam instruments for the examination of the internal material of thin specimens. This is shown by way of example in FIG. 10, wherein the scanning part of the stub is attached to means 57 holding a thin specimen 59 for TESEM examination as used in prior art D3 but now with a stationary beam, which affords all the advantages of the previous embodiment. Therefore, instruments with ultra-high resolution at high chamber pressure can now be designed and devoted to new areas of novel practical applications not previously possible.

It should be appreciated that all disclosed embodiments in this invention can be combined with any desired detection mode of the emanating signals from the beam-specimen interactions without departing from the spirit of the invention. Said detectors include, but not limited to, the detection of secondary electrons, backscattered electrons, x-rays and cathodoluminescence. Any or all of said detectors can be placed above or below the specimen, while said specimen can be presented in bulk or thin section form. The orientation of the particle beam column can be in any direction without departing from the spirit of the invention. In addition, the specimen can be observed and examined simultaneously or alternatingly with a light microscope, which also falls within the scope of the invention. By way of example of these variations and incorporations, FIG. 11 shows an embodiment like in FIG. 10 but with an upside-down (inverted) particle beam column 55 with a thin section specimen 59 held by suitable means 64 surrounded with a multiplicity of detectors 61, 62 and 63 for corresponding signals 61′, 62′ and 63′ emanating from the specimen. A light microscope 60 is used to observe and study a particular feature of a specimen in conjunction with other detection modes. The specimen holder 64 can also be used as detector of signals from the beam-specimen interactions. Again, the specimen holder is attached onto 53 that is micro-scanned by 52 relative to 54 that is held by the previously described macro-control stage. This particular embodiment allows for examination of specimens at ambient conditions and in situ in a natural state without the impediments and artifacts of hypobaric pressure or vacuum inside an enclosed chamber.

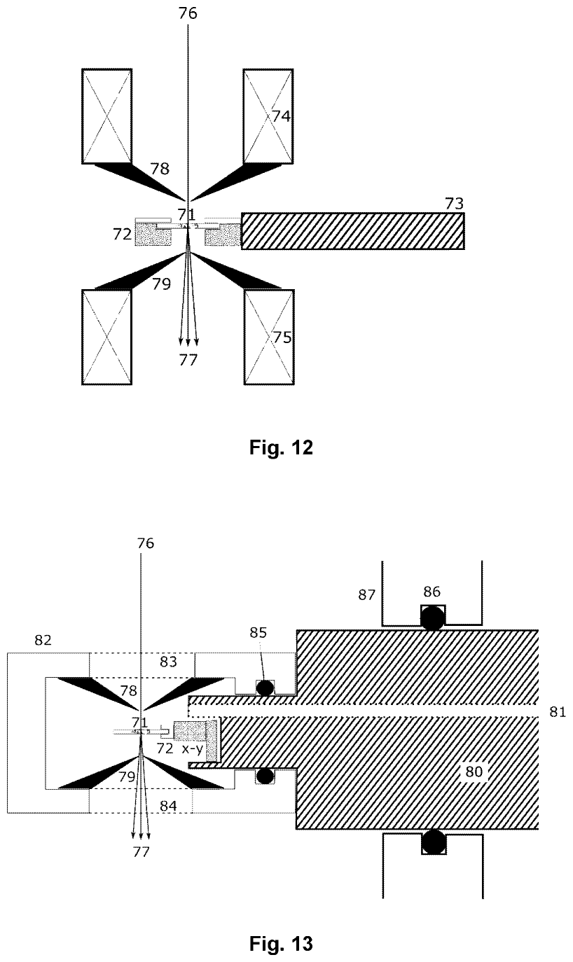

A further embodiment of the invention in conjunction with a stationary electron beam is provided by the drawing in FIG. 12. A thin specimen section 71 supported by holder 72 is inserted in the specimen chamber of a transmission electron microscope (TEM) with rod 73. The specimen chamber is located typically between two electron optics lenses 74 and 75 (e.g. condenser and objective), which focus the electron beam 76 on the specimen. After the beam passes through the specimen, the transmitted electrons 77 finally form an image of the specimen on a projection screen via the action of the intermediate lenses. The present invention provides two extremely small apertures above and below the specimen born by diaphragms 78 and 79 having a thin rim (edge) with a thickness preferably less than the size of the aperture. The diaphragms seal against the upper and lower electron optics system, so that the only possible gas leak takes place through the said apertures. The space between the two apertures now forms the specimen chamber, which can be exposed fully to the ambient pressure continuously, i.e. before, during and after specimen insertion without affecting its nature, such as it would occur if the pressure were to be lowered or the chamber fully evacuated per prior art practice. The specimen holder may incorporate mechanical x-y scanning on a much smaller scale (not shown) in a similar fashion used by an AFM as disclosed in the previous drawings.

With reference to FIG. 12 again, the following alternative embodiments fall within the scope of the present invention:

The specimen chamber may optionally be pumped to a lower pressure to allow for applications that are not adversely affected by a hypobaric pressure, or vacuum, if needed.

The ambient gas may be replaced by another gas, inert or reactive, to further assist and expand the scope of applications.

The specimen holder may optionally incorporate additional detectors, such as an x-ray detector, or an electron detector, etc. Similar detectors may also be provided in any convenient location inside the provided specimen chamber.

A final embodiment of the invention is shown in FIG. 13 without limiting the scope of the invention. Again, a thin specimen section 71 is carried by specimen holder 72, which incorporates mechanical x-y micro-scanning such as provided with an AFM. The integrated holder with micro-scanning means are fixed at the end of rod 80 for inserting the specimen as in conventional TEM, except that the rod contains a pathway (pipe) 81 to allow passage of ambient or other gas around the specimen. The same passage can be used for electrical feedthroughs to drive the scanning elements. The specimen is enveloped by the wall of a micro-chamber 82 bearing two co-axial holes 83 and 84 abutting two co-axial diaphragms 78 and 79 with extremely small apertures. The microchamber fits removably around the end of rod 80 with a suitable sealing 85 to prevent gas leaking in the vacuum of the optics column except via the provided apertures. Sealing means 86 is also provided on the optics column wall 87 around the rod 80 in the usual way to prevent ambient gas leaking into the vacuum of the column when the rod is inserted during examination. The electron beam 76 is focussed on the specimen via the condenser lenses. The transmitted beam 77 is then used to form an image at high magnification as by conventional electron-optical means.

The general object of the embodiments in FIGS. 12 and 13 is to expand prior art D1 and D2 to include the electron optics of a TEM for operation in a gaseous environment up to full ambient pressure. This is now achieved by use of extremely small and thin (sharp edge) PLAs and, preferably, by suitable mechanical means to shift and scan the specimen under the stationary beam. Whereas the use of PLAs in environmental cells in TEM constitutes prior art, the consequence and great advantages obtained by use of extremely small size apertures have not been realized in the hitherto practice of electron microscopy and related charged particle beam technologies: The quantitative reduction in the size of the apertures brings about a significant qualitative difference, which constitutes one of the inventive steps of the invention. However, by such small PLAs, the field of view is limited at low magnifications, e.g. below 100000×, so that only a very small portion of the specimen area can be imaged at any given time. This limitation has prevented the use of extremely small PLAs in prior art. Now, to mitigate this limitation, the specimen is scanned by mechanical means such as those employed in AFM. The specimen is imaged consecutively (serially) and the information is digitally stored for subsequent study. The speed of scanning is adjusted so that the image contrast is satisfactory. In consequence of the extremely small size PLA, the gas leaking through it, even at ambient pressure, is negligible. Furthermore, there is practically no beam scattering and loss inside the optics column, which is otherwise inevitable by prior art. This is because the supersonic jet forming downstream of a PLA at ambient pressure is of the order of the PLA size, which now eliminates the adverse effects on beam transmission inevitable in prior practice. Furthermore, the depletion zone upstream of the PLAs (i.e. inside the chamber) is minimal, namely, also being of the size of the aperture itself; this restricts gas streaming only extremely close to the PLA, whilst a stagnation condition prevails practically everywhere inside the chamber. The transitional variation of gas pressure is practically a step function (i.e. abrupt from vacuum to ambient), as it should be in an ideal design and optimum differential pumping system. Thus, practically the entire chamber is free for specimen positioning (movement) between the two PLAs, which also allows the total gas layer to become minimal. In consequence of all above, the only beam scattering occurs in the immediate region around and inside the specimen, which is practically the same or very close to the operation of a TEM in vacuum. Thus, the conventional TEM can be freed for the examination of any specimen at ambient pressure with no specimen damage due to vacuum and with no loss of resolution.

In outlining the above description of the invention, it is assumed that the electron optics requirements are fully accounted for and are taken into consideration for the actual values of all design parameters involved. For example, the size of PLA at the exit of the transmitted beam on the side of the objective lens (to be called PLA2), should be adjusted to be consistent with a good or optimum objective diaphragm angle value in the range of 10-25 mrad. If the specimen section is located 100 micro-meters above this PLA2, then the diameter of this aperture should be in the range of 2-5 micro-meters. By lowering the distance of the specimen to PLA2, we can accordingly make the size of this aperture even smaller. The first aperture (to be called PLA1) nearest to the condenser lens can be chosen around 1 micro-meter and will define the field of view at the lowest possible magnification. Now, the distance of PLA1 from the specimen can be minimized down to several aperture diameters, where the stagnation condition of the atmospheric gas is maintained (no streaming and depletion of gas). The attainment of such very small working distance is physically allowed only by the present invention and is limited only by the engineering precision available. As a result, the total gaseous layer thickness is determined by the distance between PLA1 and PLA2 only, whilst there is practically no other gas thickness in the remaining electron optics column. By such minimal gas thickness in the specimen chamber, the electron beam loss and accompanying signal noise are minimal or negligible, which allows the contrast produced to arise predominantly from the properties of the specimen section under examination at the lowest beam accelerating voltage. Therefore, the ultimate smallest size choice for either or both PLAs depends on the engineering precision used for the location and movement of the specimen in the confined space between PLA1-PLA2. Clearly, as these apertures become ever smaller, they may take over (even replace) the function of the adjacent condenser and objective diaphragms already in operation under vacuum for a conventional TEM. These are also interdependent on the accelerating voltage used (high or ultra-high). The engineering choices are left to the manufacturer to determine for all practical purposes, including aperture materials, specimen scanning controls, etc., and manufacturing costs. These engineering choices are finally dependent on the type of gaseous atmosphere (nature and pressure of gas) that should ultimately be allowed to use with any given application, whilst none of said choices are departing from the spirit of the present invention.

### INDUSTRIAL APPLICABILITY

By virtue of the simplicity, ease of operation, increased specimen examination rate and minimum bulkiness of the multipurpose specimen chamber, this invention has limitless industrial applications in conjunction with SEM, ESEM, TESEM, ETEM and ion microscopy.

The device of the present invention can also be used in conjunction with other instruments requiring vacuum, or controlled gaseous environment around specimens.

One particular industrial application is in the field of geological exploration and mining industry, especially because the entire device can be made compact, light and transportable to the field, and for in situ specimen examination.

Yet another application is with instruments of planetary exploration, such as on planet Mars having a thin atmosphere with a pressure two orders of magnitude less than Earth. Martian atmospheric conditions allow and require for transportation a miniaturized multipurpose device for the study of the surface and atmosphere of the planet. Considering the dusty conditions on Mars, the provision of a clean gas supply around the PLA and specimen would ensure a fault-free operation.

Existing scanned beam instruments can be greatly enhanced, simplified and applied to novel areas of industrial applications by use of a stationary probe in conjunction with mechanical scanning provided by the specimen control means of the present invention. This embodiment provides great advantages not only in general microscopy but also in microfabrication technologies using focussed particle beams to manufacture electronic or other devices with the finest structures in an open or controlled gaseous environments. Inspection by imaging and microfabrication can be integrated by a single machine with maximum controls and output efficiencies.

Another application is in biological research and development, since specimens can now be observed and studied at ambient or other environmental conditions with high resolution. When combined with light microscopy, it can advance the technology of molecular biology to novel ways of exploration.

The above embodiments disclosed having a mechanically scanned specimen in conjunction with a stationary particle beam constitute effectively a new technology that bridges the established prior art technologies of electron microscopy with atomic force or tunnelling microscopies. This opens a completely new frontier of industrial applications.

### PATENT LITERATURE

D1: U.S. Pat. No. 6,396,064 B1 patent (Danilatos)

D2: PCT/AU2016/050757 (Danilatos)

### OTHER LITERATURE

D3: Danilatos G, Kollia M, Dracopoulos V (2015) Transmission environmental scanning electron microscope with scintillation gaseous detection device. Ultramicroscopy 150, 44-53. doi:10.1016/j.ultramic.2014.11.010

1-10. (canceled)

11. An environmental charged particle beam microscope comprising an open-ended optics column for generating and focussing a charged particle beam, such as electrons or ions, comprising:
(a) a charged particle beam;
(b) a pressure limiting aperture separating the vacuum of the column from the gaseous environment allowed beyond the end of the column;
(c) an envelope optionally surrounding and abutting the end of the said column to form a specimen chamber wall comprising flexible and/or shiftable walls;
(d) a multi-directional motion stage placed at ambient (external) conditions;
(e) a specimen stub coupled with the multi-directional motion stage;
(f) the specimen stub configured to permit a specimen, when positioned in or on the specimen stub to be impinged by the particle beam; and
(g) an environmental gas inlet configured to permit environmental gas to be admitted inside the envelope.

12. The microscope according to claim 11, wherein the envelope comprises flexible and/or shiftable walls, and wherein the specimen stub is removably coupled to the multi-directional motion stage via a sealingly locking port plate configured to be moveable and removable with respect to the specimen chamber wall.

13. The microscope according to claim 11, wherein the gas inlet comprises an annular opening around the pressure limiting aperture for the formation and delivery of a gaseous annular jet along and around the path of the particle beam all the way to the specimen.

14. The microscope according to claim 11, wherein:
(a) the charged particle beam is stationary;
(b) the pressure limiting aperture is marginally larger than the charged particle beam passing through; and
(c) the multidirectional motion stage comprises a bidirectional micro-scanner for the control of the specimen.

15. The microscope according to claim 13, wherein the gaseous annular jet is delivered either at sufficient subsonic speed to remove overlaying loose particles from a specimen surface and to prevent contamination in the open-ended optics column, or at supersonic speed to provide pumping action on the gas from the open-ended optics column towards the specimen chamber.

16. The microscope according to claim 11, further comprising a light optical microscope using photons configured to permit the simultaneous or sequential examination and imaging of the specimen by the charged particle beam microscope together with the added light optical microscope.

17. The microscope according to claim 11, wherein the specimen chamber is evacuated by the naturally occurring gas flow (gas leak) through the pressure limiting aperture separating the open-ended optics column from the specimen chamber in order to obtain a desired pressure environment in the specimen chamber.

18. The microscope according to claim 17, wherein the leaking gas is replenished by a method selected from the group consisting of: (i) supplying the gas from ambient gas via a leak valve; (ii) supplying the gas from ambient gas through an annular opening around the pressure limiting aperture; and (iii) recirculating the gas from the open-ended optics column.

19. The microscope according to claim 14, further comprising:
(a) a transmission electron microscope;
(b) a specimen chamber with ambient atmosphere separated from the optics column by a set of two apertures with each having a micro-meter range opening in order to suppress the adverse effects of the supersonic air jets and depletion zones forming in the direction of the environmental gas flow through the apertures; and
(c) a thin specimen section in the specimen chamber configured to be movable in order to sequentially (consecutively, or serially) survey and store information from any desired area of the specimen.

20. The microscope according to claim 14, further comprising:
(a) a transmission electron microscope;
(b) an insertable micro-chamber comprising a set of two apertures each having a micro-meter range opening in order to suppress the adverse effects of the supersonic air jets and depletion zones forming in the direction of the environmental gas flow through the apertures; and
(c) a thin specimen section in the insertable micro-chamber configured to be movable and scanned in order to sequentially (consecutively, or serially) survey and store information from any desired area of the specimen.

21. The microscope according to claim 11, wherein the specimen is mechanically controlled with an atomic force microscope scanner.

22. The microscope according to claim 11, wherein the charged particle beam is a stationary charged particle beam, wherein the pressure limiting aperture has a diameter slightly greater than the diameter of the stationary charged particle beam, wherein the microscope further comprises:
(a) a bidirectional micro-scanner configured to control the specimen stub and result in imaging of the specimen by use of the signals from beam-specimen interactions without vignetting; and
(b) the bidirectional micro-scanner operating either inside a chamber with a controlled gaseous environment or operating in the absence of a chamber beyond the open-ended optics column at ambient pressure on account of the diameter of the pressure limiting aperture.

23. The microscope according to claim 22, wherein the bidirectional micro-scanner comprises piezo-electrical elements that provide deformation when an electrical signal is applied thereto.
